(19) United States
(12) Patent Application Publication
(10) Pub. No.: US 2004/0112721 A1
(43) Pub. Date: Jun. 17, 2004

(54) Multiple key assembly for electronic device

(76) Inventors: Wang Tien Chao, Tu-chen (TW); Chun Jen Lin, Tu-chen (TW); Kin Liu, Shenzhen (CN); John Chen, Shenzhen (CN); Max You, Max (CN)

Correspondence Address: WEI TE CHUNG, FOXCONN INTERNATIONAL, INC., 1650 MEMOREX DRIVE, SANTA CLARA, CA, 95050, US

(21) Appl. No.: 10/423,412

(22) Filed: Apr. 24, 2003

(30) Foreign Application Priority Data
Dec. 13, 2002 (TW) 91220224

(51) Int. Cl. H03M 11/00

(52) U.S. Cl. 200/5 A

(57) ABSTRACT

A multiple key assembly (100) includes a multiple key including a central key (1) and four key segments (2) separated from each other, a base member (4) having a base (42), a circular platform (44), a plurality of connecting parts (46) flexibly connecting the circular platform with the base and a PCB (6). A plurality of contacts (49) is provided on bottoms of the circular platform and the connecting parts, and the PCB provides a plurality of contact pads (62) corresponding in position to the contacts on the base member. During assembly, the multiple key is first mounted on the base member and then both are secured to the PCB with the plurality of contacts of the base member suspended above the corresponding contact pads on the printed circuit board. If desired, an elastic spacer (3) and/or a key sheath (5) can be included.

### FIELD OF THE INVENTION

The present invention relates to data input devices for electronic devices and, more particularly, to multiple key assemblies for electronic devices.

### BACKGROUND OF THE INVENTION

Nowadays, there is a considerable consumer demand for electronic devices having a small form factor, and there is also a competing consumer demand for such electronic devices that include more and more features. This competing demand generally translates into greater data processing and display capabilities, which typically requires greater real estate in the electronic device. With regard to display capabilities, it is considered desirable to provide an electronic device with as large a display screen as practical. However, increasing the size or viewable area of a display screen associated with a small form factor electronic device leaves little room for data entry from a conventional keypad matrix, such as a keypad matrix shown in U.S. Pat. No. D 416,024. It is not practical to continue reducing the size and/or the spacing of the buttons that form a conventional keypad matrix arrangement.

To overcome the foregoing difficulties, U.S. Pat. No. 6,157,323 discloses a multiple key assembly to integrate a plurality of key segments together, resulting in a keypad matrix occupying less room. A similar multiple key assembly is also described in U.S. Pat. No. 6,441,753. Both the multiple key assemblies can rotate around a pivot so that a user can select and depress a specific key segment to electrically connect with a printed circuit board (PCB) while the other key segments remain disconnected. However, because the key segments of the above multiple assemblies are integral, when a key segment is depressed, the other key segments maybe also be depressed or influenced and thus an incorrect manipulation frequently occurs. In addition, the sense of depressing the key segment is not satisfactory due to the bad elasticity of the multiple key assemblies.

Therefore, an improved multiple key assembly of an electronic device is desired to overcome the disadvantages of the prior art.

### SUMMARY OF THE INVENTION

A main object of the present invention is to provide a multiple key assembly for an electronic device which can avoid incorrect manipulation thereof.

Another object of the present invention is to provide a multiple key assembly for an electronic device which provides a good sense of manipulation.

To achieve the above objects, a multiple key assembly of an electronic device comprises a central key, four key segments for surrounding the central key, a base member and a printed circuit board. The central key and the four key segments are separated from each other. The base member has an outer portion called a base, a central portion called a circular platform, and a plurality of connecting parts flexibly connecting the circular platform with the base. A plurality of contacts is provided on bottoms of the circular platform and the connecting parts. The printed circuit board provides a plurality of contact pads corresponding in position to the contacts on the base member. During assembly, the central key and the four key segments are first mounted on the base member and then the base member with the keys is secured to the printed circuit board with the plurality of contacts of the base member suspended above the corresponding contact pads on the printed circuit board. When manipulating the keys, one of the keys is pressed to make the circular platform or the corresponding connecting part move downwardly until the contact corresponding in position to the key contacts with the corresponding contact pad on the printed circuit board and a circuit is closed. When the key is released, the depressed key will recover to its original position under the elastic force exerted by the circular platform of the base member. If desired, an elastic spacer can be mounted on the base member to increase the elastic force exerted against the four key segments. Of course, a key sheath also can be included to cover the multiple key assembly.

Other objects, advantages and novel features of the invention will become more apparent from the following detailed description of a preferred embodiment thereof when taken in conjunction with the accompanying drawings, wherein:

### BRIEF DESCRIPTION OF THE DRAWINGS

FIG. 1 is an exploded, perspective view of a multiple key assembly of an electronic device in accordance with a first embodiment of the present invention viewed from a top aspect;

FIG. 2 is an exploded, perspective view of the multiple key assembly of FIG. 1, viewed from a bottom aspect;

FIG. 3 is a perspective view of the assembled multiple key assembly of FIG. 1 viewed from a top aspect;

FIG. 4 is a perspective view of the assembled multiple key assembly of FIG. 3 viewed from a top aspect; and

FIG. 5 is an exploded, perspective view of a multiple key assembly of an electronic device in accordance with a second embodiment of the present invention.

### DETAILED DESCRIPTION OF THE INVENTION

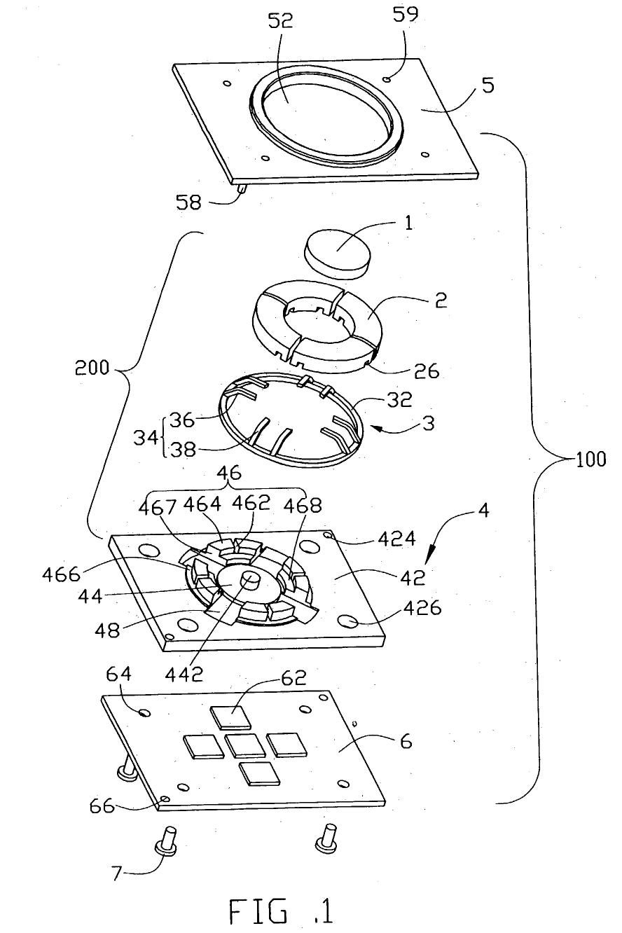

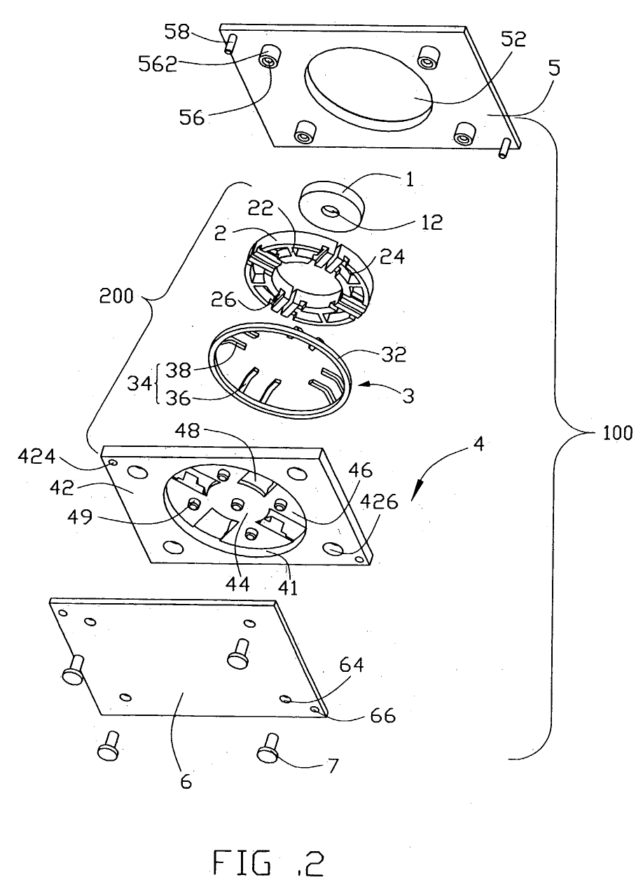

With reference now to the drawings in detail, FIGS. 1 and 2 show a multiple key assembly 100 for an electronic device in accordance with a first embodiment of the present invention. The multiple key assembly 100 comprises a central key 1, a plurality of key segments 2, an elastic spacer 3, a base member 4, a key sheath 5, a printed circuit board (PCB) 6 and a plurality of bolts 7.

The central key 1 has the shape of a flat cylinder and define a blind hole 12 in its bottom. The key segments 2 are separated from each other and constitute a ring-shaped configuration. Each key segment 2 is substantially a hollow cover with a cavity defined in its bottom; said cavity is divided into two engaging holes 24 by a central wall 22 thereof. Two gaps 26 are formed in the bottom of each key segment 2 adjacent to two ends thereof and respectively communicate with the two engaging holes 24. The central key 1 and the key segments 2 constitute a multiple key (not labeled). The elastic spacer 3 has a ring 32 and a plurality of pairs of elastic legs 34 extending therefrom. Each pair of elastic legs 34 comprises a first leg 36 and a second leg 38, which are positioned and shaped to engage with the gaps 26 of a single key segment 2.

The base member 4 has an outer portion, called a base 42, a central portion, called a circular platform 44, which is formed in a middle of the base 42 and a plurality of connecting parts 46 connecting the base 42 with the circular platform 44. A protrusion 442 extends upwardly from the circular platform 44. A bottom surface (not labeled) of the circular platform 44 is coplanar with bottom surfaces (not labeled) of the connecting parts 46 and is spaced above a bottom surface (not labeled) of the base 42, thus a shallow concavity 41 is formed beneath the circular platform 44 and the connecting parts 46. Also, a plurality of spaces 48 is defined between the connecting parts 46. Each connecting part 46 has a stepped configuration and forms three steps having different heights, i.e., a lowest seat 466, an interior step 468, and a highest step 467 between the seat 466 and the interior step 468. A slot 462 is formed in a middle of the step 467 of the connecting part 46 to divide the step 467 into two engaging tabs 464. A plurality of contacts 49 respectively extends from the bottom surfaces of the circular platform 44 and the connecting parts 46. In the present invention, said contacts 49 are preferably positioned at a middle of said bottom surfaces. A plurality of tab holes 426 and pin holes 424 are provided in the base 42.

The key sheath 5 has a round opening 52 to receive the central key 1 and the key segments 2 therein. A plurality of pins 58 and locating tabs 562 extend from a bottom surface of the key sheath 5. Said locating tabs 562 each having a receiving hole 56 in a middle thereof and a height thereof is substantially identical with a thickness of the base 42. On a top surface of the key sheath 5 corresponding in position to the receiving holes 56 there are a plurality of glue-receiving openings 59 which communicate with the receiving holes 56, respectively. The PCB 6 also has a plurality of bolt holes 64 and pin holes 66 defined therein. A plurality of contact pads 62 is provided on the PCB 6 corresponding in position to the contacts 49 of the base member 4.

During assembly, first, the elastic spacer 3 is placed on the base member 4 so that the ring 32 is positioned on the seats 466 of the connecting parts 46 and the plurality of pairs of elastic legs 34 are respectively received in the corresponding gaps 26. A top surface of the ring 32 on the seats 466 now is coplanar with a top surface of the interior steps 468, thus ensuring the key segments 2 can be stably mounted thereon. Then, the key segments 2 are respectively assembled on the corresponding connecting parts 46 of the base member 4. Accordingly, the engaging tabs 464 are received in the corresponding engaging holes 24 and the central walls 22 are inserted into the corresponding slots 462. Also, each pair of the elastic legs 34 are engaged with the two gaps 26 of the corresponding key segment 2. In a third step, the central key 1 is assembled on the circular platform 44 with the protrusion 442 engaging with the blind hole 12 and all the key segments 2 being arranged around the central key 1. Thus, assembly of a multiple key subassembly 200 is finished.

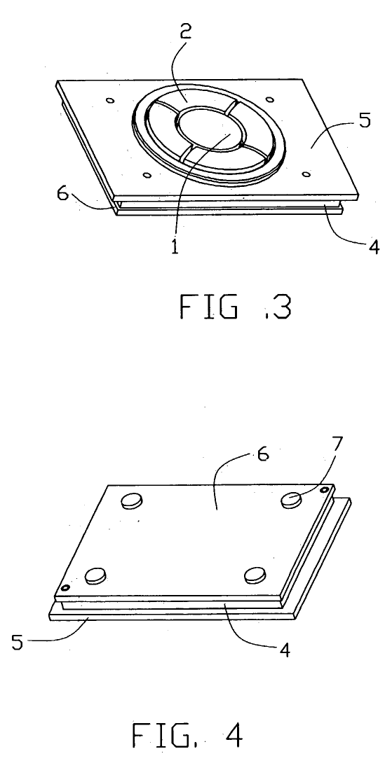

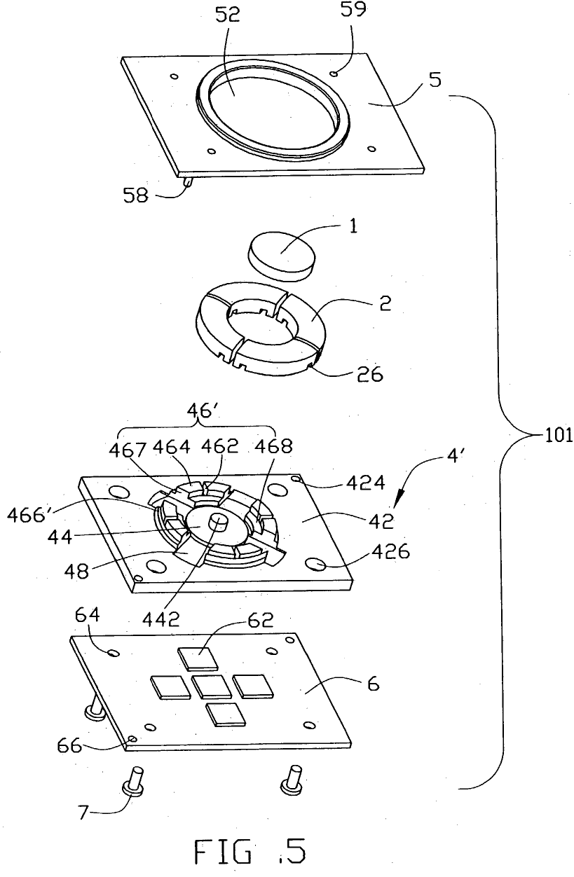

To assemble the multiple key subassembly 200 to an electronic device, the locating tabs 562 and the pins 58 of the key sheath 5 are passed through the corresponding tab holes 426 and pin holes 424 of the base member 4, while the central key 1 and the key segments 2 extend through the round opening 52 of the key sheath 5. Bottom surfaces of the locating tabs 562 are then abutted against a top surface of the PCB 6 at positions corresponding bolt holes 64 of the PCB 6, and the exposed portions of the pins 58 threaded through the pin holes 424 are further extended through the pin holes 66 of the PCB 6, while the axes of the corresponding receiving holes 56, tab holes 426 and bolt holes 64 coincide with each other. At this point, the contacts 49 of the base member 4 are suspended above the corresponding contact pads 62 of the PCB 6. Then the plurality of bolts 7 is extended through the corresponding bolt holes 64 and into the corresponding receiving holes 56. The bolts 7 are fixedly engaged in the receiving holes 56 by a glue dripping through the glue-receiving openings 59 of the key sheath 5 into the receiving holes 56. Thus a whole assembly of the multiple key assembly 100 is attained, as shown in FIGS. 3 and 4. It is easily understood that the pins 58 can also be fixed in the pin holes 424 and 66 by glue. Further, the central key 1 and the key segments 2 can be fixed to the base member 4 using the glue.

When manipulating the multiple key of the multiple key assembly 100, a key segment 2 or a central key 1 is pressed downwardly. If a key segment 2 is pressed, the corresponding elastic legs 34 and the corresponding connecting part 46 downwardly move until the contact 49 on the connecting part 46 contacts with the corresponding contact pad 62 and a circuit is closed. When the key segment 2 is released, it recovers to its original position under the elastic force exerted by the base member 4 and the elastic spacer 3. If a central key 1 is pressed downwardly, the circular platform 44 downwardly moves until the contact 49 on the underside of the circular platform 44 contacts the corresponding contact pad 62 on the PCB 6 and the circuit is closed. When the central key 1 is released, it recovers to its original position under the elastic force exerted by the base member 4.

According to another embodiment of the present invention, the elastic spacer member 3 can be omitted from the multiple key assembly 100 to form a multiple key assembly 101, as shown in FIG. 5. In this embodiment, the base member 4′ is modified to make the seats 466′ of the connecting parts 46′ coplanar with the interior steps 48 so as to stably mount the key segments 2 directly thereon without the help of the ring 32 of the elastic spacer 3. Obviously, the multiple key subassembly 200 can be directly assembled on the PCB 6 by other convention connection methods, and thus the key sheath 5 can also be omitted.

The central key 1 and the key segments 2 are separated from each other, so it is easy to distinguish them from each other when manipulating the multiple key assembly 100 or 101, and to thus avoid wrongly depressing the key segments 2 or the central key 1. In addition, because there is an enough space 48 between every two key segments 2 so that a depressed key segment 2 will not overly influence the adjacent key segments 2, unwanted electrical connections between other key segments 2 and the PCB 6 are avoided. Furthermore, because of the elastic connection between the circular platform 44 and the base 42 through the plurality of connecting parts 46, the sense of manipulating the multiple key assembly 100 or 101 becomes more comfortable and a depressed key segment 2 or depressed central key 1 recovers more quickly. Of course, using the elastic spacer 3 can strengthen the above effects.

It will be apparent that many changes and modifications of the several features described herein may be made with departing from the spirit and scope of the invention. It is therefore apparent that the foregoing description is by way of illustration of the invention rather than limitation of the invention.

What is claimed is:

1. A multiple key assembly of an electronic device comprising:
a multiple key comprising a plurality of key segments, wherein said key segments are separated from each other;
a base member having an outer portion, a central portion, and a plurality of connection parts flexibly connecting the central portion with the outer portion;
a plurality of contacts provided on a bottom of the central portion and the connection parts;
a printed circuit board providing a plurality of contact pads corresponding in position to the contacts on the base member;
wherein the multiple key is mounted on the base member and then the base member with the multiple key is secured to the printed circuit board with the plurality of contacts of the base member suspended above the corresponding contact pads on the printed circuit board.

2. The multiple key assembly of an electronic device as claimed in claim 1, further comprising an elastic spacer mounted on the base member.

3. The multiple key assembly of an electronic device as claimed in claim 2, further comprising a key sheath with an opening therein mounted on the base member such that the multiple key extends through the opening.

4. The multiple key assembly of an electronic device as claimed in claim 1, wherein the multiple key comprises a central key and a plurality of key segments encircling the central key.

5. The multiple key assembly of an electronic device as claimed in claim 2, wherein the elastic spacer comprises a ring and a plurality of pairs of elastic legs extending therefrom.

6. A multiple key assembly of an electronic device comprising:
a multiple key comprising a central key and a plurality of key segments, wherein said key segments and the central key are separated from each other;
an elastic spacer;
a base member having an outer portion, a central portion, and a plurality of connecting parts flexibly connected the central portion with the outer portion;
a plurality of contacts provided on a bottom of the central portion and the connecting parts;
a printed circuit board providing a plurality of contact pads corresponding in position to the contacts on the base member;
wherein the elastic spacer is mounted on the base member, and then the multiple key is mounted on the base member, lastly, the base member with the multiple key and the elastic spacer is secured to the printed circuit board with the plurality of contacts of the base member suspending above the corresponding contact pads on the printed circuit board.

7. The multiple key assembly of an electronic device as claimed in claim 6, wherein the central portion forms a protrusion in a middle of an upper surface thereof and a bottom surface of the central portion is coplanar with bottom surfaces of the connecting parts and is separated a distance from a bottom surface of the outer portion.

8. The multiple key assembly of an electronic device as claimed in claim 7, wherein a plurality of spaces is defined between the connecting parts.

9. The multiple key assembly of an electronic device as claimed in claim 8, wherein each connecting part has a stepped configuration and forms three steps, each step having a different height.

10. The multiple key assembly of an electronic device as claimed in claim 9, wherein a slot is formed in a middle of the highest step of each connecting part to divide the highest step into two engaging tabs.

11. The multiple key assembly of an electronic device as claimed in claim 10, wherein the central key has the shape of a flat cylinder and defines a blind hole in its underside, and the separated key segments together form a ring-shaped configuration.

12. The multiple key assembly of an electronic device as claimed in claim 11, wherein each key segment is substantially a hollow cover with a cavity defined in its bottom and said cavity is divided into two holes by a central wall thereof.

13. The multiple key assembly of an electronic device as claimed in claim 12, wherein two gaps are formed in the bottom of each key segment adjacent to two ends thereof, which two gaps respectively communicate with the two holes.

14. The multiple key assembly of an electronic device as claimed in claim 6, further comprising a key sheath with an opening therein mounted on the base member such that the multiple key extends through the opening.

15. The multiple key assembly of an electronic device as claimed in claim 14, wherein the key sheath has engaging members to engage with engaging means of the base member and the printed circuit board and for combining the key sheath, the base member and the printed circuit board together.

16. A multiple key assembly comprising:
a plurality of key segments circumferentially arranged while discrete from one another with a first space between every adjacent two of said key segments; and
a base member located under said key segments and integrally including a plurality of up and down moveable connection parts circumferentially arranged while discrete from one another with a second space between every adjacent two of said connection parts, said key segments vertically aligned and engaged with the corresponding connection parts, respectively; wherein
each of said key segments is associatively moveable along with the corresponding connection part while is further assistantly upwardly supported by a respective resilient device which is discrete from the base member.

17. The assembly as claimed in claim 16, wherein said resilient device is located in the second space.

18. The assembly as claimed in claim 16, wherein aid second space is larger than the first space.

19. The assembly as claimed in claim 16, wherein a central key is outwardly radially linked to said key segments, and said base member further includes a central platform outwardly radially linked to said connection parts and vertically aligned and engaged with said central key.

20. The assembly as claimed in claim 19, wherein said central key is not upwardly supported by said resilient devices.
